(19) United States
(12) Patent Application Publication
(10) Pub. No.: US 2026/0136869 A1
(43) Pub. Date: May 14, 2026

(54) System and Method for Accelerated Process Chamber Pressure Modulation

(71) Applicant: Yang Pan, SINGAPORE (SG)

(72) Inventor: Yang Pan, SINGAPORE (SG)

(73) Assignee: Inspiring Atoms Pte Ltd, SINGAPORE (SG)

(21) Appl. No.: 18/946,920

(22) Filed: Nov. 14, 2024

(51) Int. Cl. H01L 21/67; C23C 16/44; C23C 16/52

(52) U.S. Cl. CPC H10P 72/0421; C23C 16/4412; C23C 16/52; H10P 72/06

(57) ABSTRACT

Disclosed herein is a system and method for accelerated modulation of process chamber pressure, particularly advantageous in semiconductor manufacturing environments. The system utilizes a gas pressure control ring equipped with orifices and a series of responsive plungers. Plunger positions are adjusted through the application of alternating currents (AC) to coils, enabling rapid and precise pressure modulation within the chamber. The method further includes controlling coil currents and performing iterative adjustments to achieve a target pressure with high accuracy.

### FIELD

The present invention pertains to systems and methods for achieving rapid modulation of process chamber pressure, with a specific focus on expedited pressure modulation in vacuum process chambers.

### BACKGROUND

Vacuum process chambers are essential in semiconductor manufacturing for processes such as plasma-based and thermal-based deposition and etching. The performance of these processes is highly influenced by the chamber pressure, making precise and rapid pressure control crucial to achieving desired outcomes.

Current methods of chamber pressure management rely on two main factors: (1) the control of gas flow rates into the chamber through a gas distribution unit, typically a showerhead positioned at the chamber's upper portion, and (2) the extraction of gases, including reaction byproducts, by a pump paired with an overhead vacuum valve to regulate gas removal. The final chamber pressure results from a balance between these factors.

To monitor chamber pressure, a manometer is commonly used. During steady-state conditions, if the measured chamber pressure deviates from the predetermined target set by the process recipe, adjustments are made to the position of a movable component in the vacuum valve to achieve the desired pressure. This adjustment, typically performed using a proportional-integral-derivative (PID) control loop, often takes several hundred milliseconds, with the movable component's adjustment speed limiting the rate of pressure modulation.

In recent years, techniques such as atomic layer deposition (ALD) and atomic layer etching (ALE) have become increasingly significant in semiconductor manufacturing, with each requiring rapid and responsive chamber pressure modulation. This has created an urgent demand for improved methods to accelerate chamber pressure modulation.

### SUMMARY

The following summary provides an introductory overview of certain concepts that will be described in greater detail in the subsequent Detailed Description section. This summary is not intended to identify key features or essential aspects of the claimed invention, nor to limit the scope of the claimed subject matter.

In some embodiments, a process chamber comprises a chamber body, a gas distribution unit that receives gases from a source such as a gas box, a chuck to support the substrate during processing, and a pump for the removal of gases, including reaction byproducts generated in the chamber. Chamber pressures are monitored via a manometer, while a system controller facilitates pressure modulation.

In further embodiments, a chamber pressure control apparatus is implemented with a gas pressure control ring, positioned either within a ring-shaped space between the chuck and the chamber body or between the chuck's supporting structure and the chamber body. This ring effectively seals the space between the chuck and chamber body, except for orifices located within the ring. Each orifice houses a coil, managed by a driver connected to a power supply. The driver delivers alternating current (AC) from the power supply to the coil under the control of the system controller. Above each orifice sits a plunger connected to a supporting structure by a spring. The plunger's position is determined by the interplay of gravitational force, the mechanical force from the spring, and the magnetic force generated by the AC current through the coil. The current applied controls the plunger's position, enabling it to range from fully closed to fully open. In one implementation, the supporting structure is configured as a rigid ring positioned above the gas pressure control ring.

In alternative embodiments, the plungers are located below the orifices, with the springs and supporting structures positioned beneath them.

In other embodiments, the system controller governs the position of the vacuum valve's movable part above the pump, based on the process recipe's specifications. Before gas introduction into the process chamber, the movable part's position is set according to the system controller's directions and remains fixed during the process step.

In additional embodiments, the system may operate without a vacuum valve above the pump, whereby chamber pressure modulation is primarily managed by the pressure control apparatus.

Various embodiments include options for uniform current delivery to each coil, while other embodiments allow for differentiated current delivery to specific coils.

In certain configurations, the gas pressure control ring's orifices are distributed uniformly; however, in other configurations, they may be arranged non-uniformly.

These innovative embodiments provide substantial advantages over traditional chamber pressure control methods. Conventional adjustments using a valve to achieve a stable chamber pressure, as directed by the process recipe, typically require several hundred milliseconds. In contrast, the rapid positioning of a plunger using the magnetic force generated by a coil achieves modulation in significantly less than a hundred milliseconds, thereby reducing process time for ALD and ALE steps and substantially enhancing overall processing efficiency.

### BRIEF DESCRIPTION OF THE DRAWINGS

The embodiments of the invention are clarified through the following description and accompanying drawings.

FIG. 1: A schematic illustration of a conventional process system utilizing a standard chamber pressure control method.

FIG. 2: A schematic illustration of an embodiment featuring a chamber pressure control apparatus for accelerated pressure modulation.

FIG. 3A: A top view of a schematic diagram depicting an exemplary gas pressure control ring.

FIG. 3B: A top view of a schematic diagram showing the gas pressure control ring with a support structure positioned above.

FIG. 4: A functional diagram illustrating the components and interactions within the chamber pressure control apparatus.

FIG. 5: A flowchart outlining the chamber pressure modulation process using the chamber pressure control apparatus.

### DETAILED DESCRIPTION

This detailed description provides specific implementations to facilitate a thorough understanding of the invention. It should be noted that although certain details are provided for clarity, modifications within the scope of the appended claims are possible. Additionally, well-known procedures, processes, and components are not exhaustively described to prevent obscuring aspects of the present invention.

### Definition

Process Chamber—The controlled environment used in semiconductor manufacturing for processes like etching and deposition, where pressure and gas conditions are tightly regulated.
Chamber Pressure Control Apparatus—The apparatus responsible for modulating process chamber pressure, comprising the gas pressure control ring, coils, and plungers.
Gas Pressure Control Ring—A ring-shaped component within the chamber that contains orifices to regulate gas flow, allowing rapid and precise control of chamber pressure.
Orifices—Openings within the gas pressure control ring that control gas conductance, directly impacting chamber pressure.
Plunger—A movable element near each orifice in the gas pressure control ring, whose position adjusts gas flow through electromagnetic forces.
Coil—An electromagnetic component surrounding each orifice in the gas pressure control ring, activated by alternating current to control the plunger's position via magnetic forces.
System Controller—The central unit that manages the chamber pressure control apparatus, modulating coil currents and making adjustments based on pressure feedback to maintain target pressure.
Manometer—A device that measures chamber pressure, providing real-time feedback for precise pressure control by the system controller.
Vacuum Valve—A valve positioned above the pump in conventional systems to regulate gas extraction rates, affecting chamber pressure.
Proportional-Integral-Derivative (PID) Control Loop—A control mechanism that adjusts the vacuum valve to maintain target pressure.
Atomic Layer Deposition (ALD)—A deposition process in semiconductor manufacturing that builds thin films one atomic layer at a time, requiring precise chamber pressure control for uniform layer formation.
Atomic Layer Etching (ALE)—An etching process that removes material in atomic layers, relying on rapid chamber pressure adjustments to achieve consistent and precise material removal.

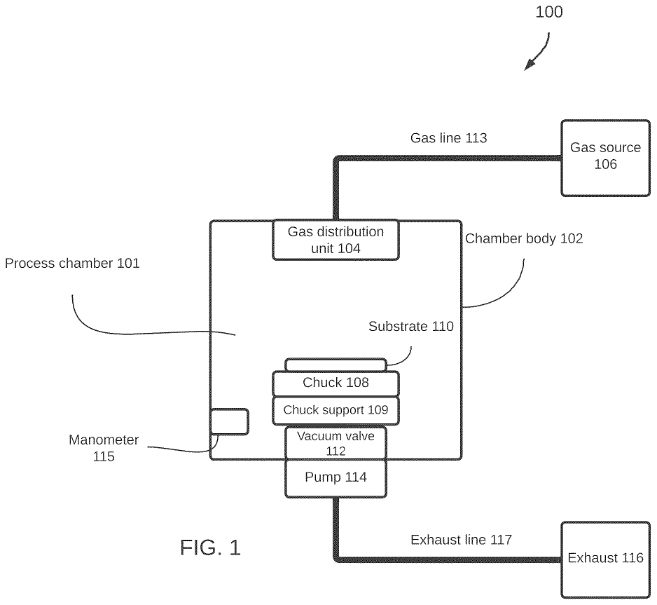

FIG. 1 illustrates a conventional process system (100) that includes a process chamber (101). The system (100) consists of a chamber body (102) that maintains a vacuum environment for reaction processes. A gas distribution unit (104), connected to a gas source (106) such as a gasbox via gas line (113), introduces gases into process chamber (101) from the top. Gas distribution unit (104) may be configured as a showerhead or injector. A substrate support chuck (108) holds the substrate (110) within process chamber (101) and may function as a vacuum chuck or electrostatic chuck. The substrate (110) is typically a silicon wafer, although other substrate types may be used. Chuck support (109) provides mechanical reinforcement and utility supply to chuck (108), creating a ring-shaped space with the chamber body (102). A pump (114) removes gases and reaction byproducts from process chamber (101) via exhaust line (117) to an exhaust (116) located above a vacuum valve (112), which plays a key role in maintaining stable pressure during reactions. A manometer (115) monitors chamber pressure, and any deviation from the target pressure triggers an adjustment of valve (112), typically taking several hundred milliseconds. With the rising importance of ALD and ALE techniques in semiconductor manufacturing, there is a demand for faster chamber pressure modulation.

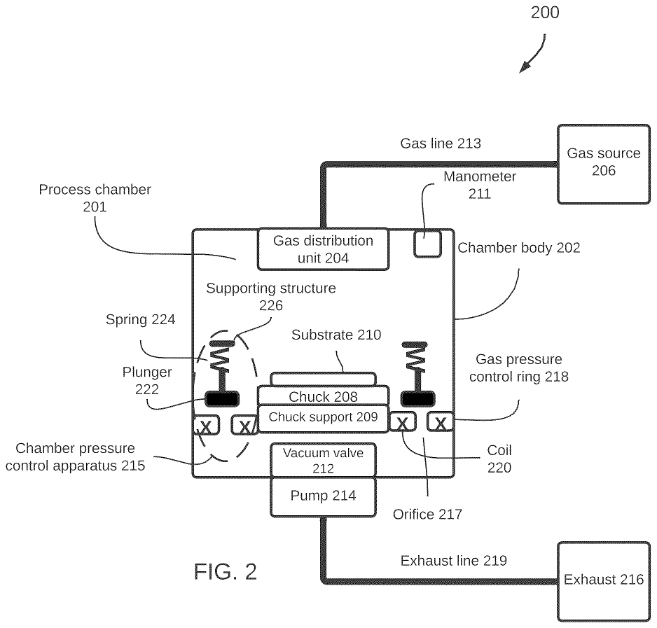

FIG. 2 presents a schematic diagram of an enhanced process system (200) as an embodiment of this invention. System (200) includes a process chamber (201) with a chamber body (202) housing a vacuum environment. Gas distribution unit (204), connected to a gas source (206) via gas line (213), introduces gases into process chamber (201) either from the top or the sidewall. A chuck (208) holds the substrate (210) during processing, functioning as a vacuum chuck or electrostatic chuck. Chuck support (209) reinforces chuck (208) and provides utility supply, defining a ring-shaped space with the chamber body (202). Gases and byproducts are extracted from process chamber (201) through pump (214) and exhaust line (219) to exhaust (216). A chamber pressure control apparatus (215) enables rapid pressure modulation. The apparatus includes a gas pressure control ring (218), which may be made of ceramic or glass, with orifices (217) that regulate gas conductance. Coils (220) are placed around each orifice (217), while plungers (222) respond to magnetic forces generated by AC currents in the coils. This configuration allows rapid pressure adjustments, optimizing process performance and stability.

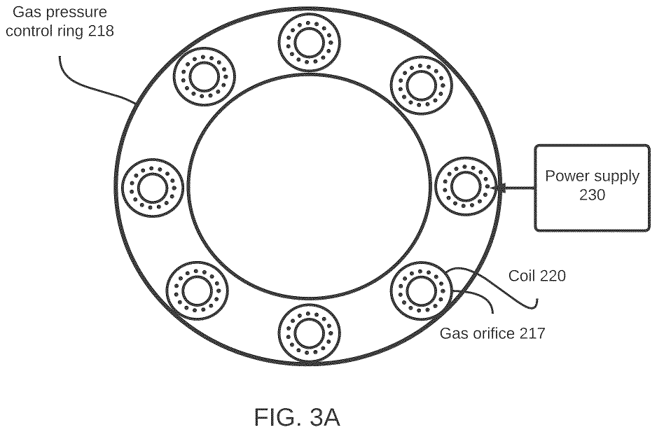

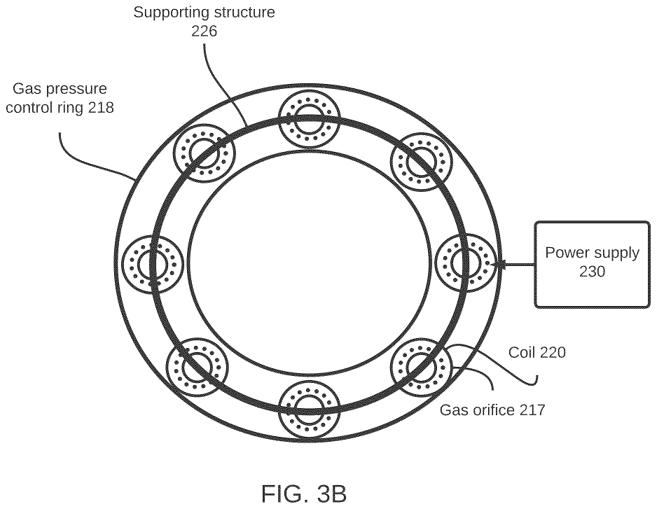

FIG. 3A offers a top view of the gas pressure control ring (218), showing the arrangement of coils (220) and the power supply connection (230). The exemplary configuration of eight evenly spaced orifices (217) can be modified to accommodate more or fewer orifices, depending on process requirements for uniformity. The number and placement of orifices may vary based on design needs. The orifice sizes may also differ.

FIG. 3B illustrates the gas pressure control ring (218) with a support structure (226) positioned above. The support structure may also be situated below the control ring (218) and may be enclosed to prevent damage from corrosive gases and byproducts.

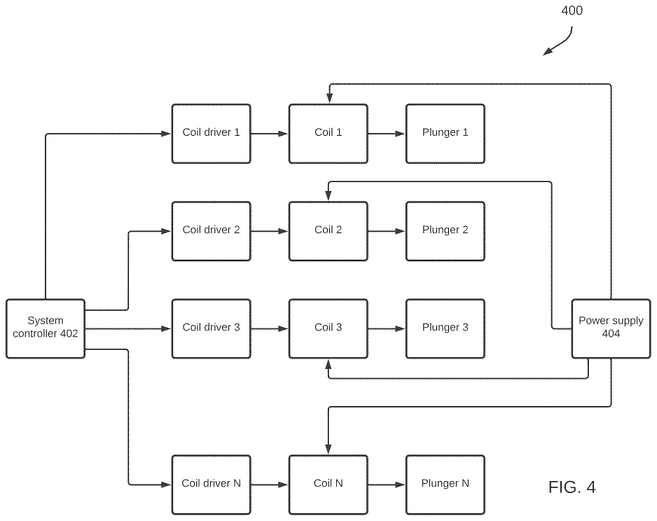

FIG. 4 shows a functional diagram of the chamber pressure control apparatus (400), comprising an array of coil drivers, coils, plungers, a system controller (402), and a power supply (404). System controller (402) manages coil drivers and current delivery, enabling precise chamber pressure modulation.

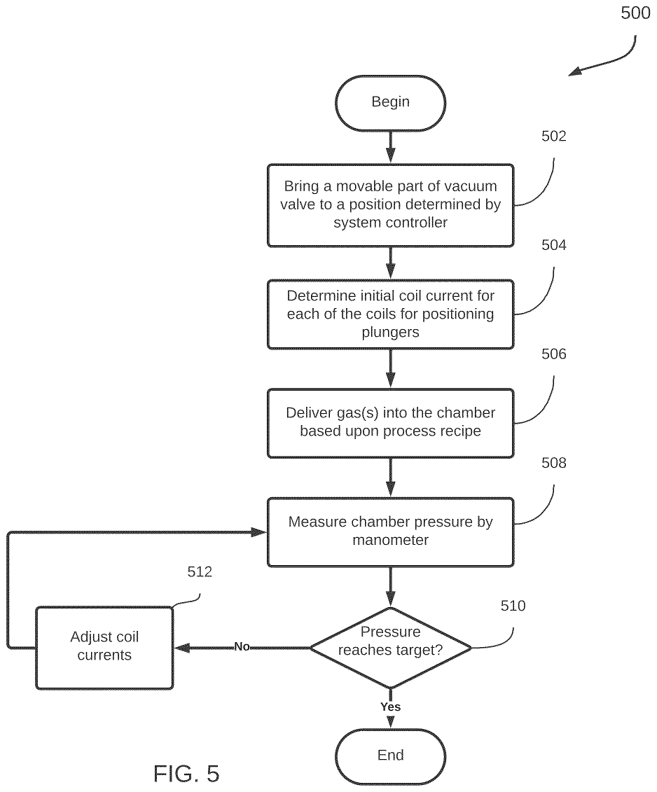

FIG. 5 depicts the process (500) for chamber pressure modulation using the chamber pressure control apparatus (215). Optionally, a vacuum valve (212) adjusts its movable part's position according to a process recipe in step 502. This position can remain fixed throughout the chamber pressure adjustment process. In step 504, coil currents are established and applied to set the positions of plungers (222). In one implementation, all coils receive identical AC currents; in another, the coils may receive differentiated AC currents. Process gases are introduced via the gas distribution unit (204) in step 506. The manometer (215) measures chamber pressure in step 508, and system controller (402) iteratively adjusts coil currents to achieve the target pressure in steps 510 and 512, with the option to expedite this process using a PID control loop.

1. A process chamber, comprising:
a chamber body;
a gas distribution unit for receiving gases from a gas source and distributing the received gases to the process chamber;
a chuck for supporting a substrate;
a pump for removing gases from the process chamber; and
a chamber pressure control apparatus for modulating chamber pressure, including a gas pressure control ring, comprising a plurality of orifices, wherein a plunger is installed above each orifice, wherein the position of the plunger is determined by an AC current flowing through a coil installed in the gas pressure control ring.

2. The process chamber of claim 1, wherein the plunger is further coupled further to a spring.

3. The process chamber of claim 2, wherein the spring is coupled to a supporting structure installed in said chamber.

4. The process chamber of claim 3, wherein the supporting structure is a supporting ring.

5. The process chamber of claim 1, wherein the amplitude of the AC current is controlled by a system controller through a driver.

6. The process chamber of claim 5, wherein the system controller further includes a PID control loop for achieving targeted pressure of the process chamber by using the chamber pressure control apparatus.

7. The process chamber of claim 1, wherein the gas pressure control ring is installed in a space between the chuck and the chamber body.

8. The process chamber of claim 1, further including a vacuum valve positioned above the pump, wherein the position of a movable part of the vacuum valve is fixed during a process step.

9. The process chamber of claim 1, further configured without a vacuum valve above the pump.

10. The process chamber of claim 1, wherein the plunger is installed either above or below the gas pressure control ring.

11. A method of modulating pressure of a process chamber including a chamber pressure control apparatus, comprising:
determining an initial coil current for each coil by a system controller, wherein the coil is a part of the gas pressure control ring installation of the chamber pressure control apparatus;
delivering determined current to the coil by the system controller through a driver;
delivering at least one gas into the process chamber;
measuring chamber pressure at a predetermined frequency by a manometer; and
adjusting the current of the coil according to measured chamber pressure by the system controller, wherein the current controls the position of a plunger, wherein the gas pressure control ring further includes a plurality of orifices.

12. The method of claim 11, further including moving a movable part of a vacuum valve above a pump to a predetermined position before the gas injection into the process chamber, wherein the position is fixed during a process step.

13. The method of claim 11, wherein the method further includes measuring pressures of the process chamber in a predetermined frequency.

14. The method of claim 11, further including delivering an identical current to each coil.

15. The method of claim 11, further including delivering a distinct current to at least one coil.

16. A process chamber pressure control apparatus, comprising:
a ring-shaped structure including a plurality of orifices;
a plurality of coils, positioned around the orifices;
a plurality of plungers, positioned above or below the orifices; and
a supporting structure, wherein each plunger is coupled to the supporting structure through a spring; wherein the position of the plunger is at least determined by an AC current flowing through the coil.

17. The apparatus of claim 16, further including a system controller for controlling its operations.

18. The apparatus of claim 16, wherein the supporting structure is a ring-shaped structure.

19. The apparatus of claim 16, wherein the coils are connected to a power supply through a driver.

20. The apparatus of claim 16, wherein said ring-shaped structure is installed in a space between a chuck and a chamber body.
